(19) United States
(12) Patent Application Publication
(10) Pub. No.: US 2013/0134898 A1
(43) Pub. Date: May 30, 2013

(54) Light Emitting Diode Producing Any Desired Color

(71) Applicant: Eric W. B. Dias, Bangalore (IN)

(72) Inventor: Eric W. B. Dias, Bangalore (IN)

(73) Assignee: INTERNATIONAL BUSINESS MACHINES CORPORATION, Armonk, NY (US)

(21) Appl. No.: 13/306,131

(22) Filed: Nov. 29, 2011

(51) Int. Cl. H05B 37/02; H01L 33/08

(52) U.S. Cl. 315/291; 257/89; 257/E33.047

(57) ABSTRACT

A light emitting diode (LED), wherein the LED comprises a plurality of active regions, each of the plurality of active regions of the LED configured to produce a distinct emission falling within a primary wavelength range, the LED further configured to control the intensity of the distinct emission from each of the plurality of active regions thereby producing an output emission in a wavelength range of any desired color.

### FIELD OF THE INVENTION

Embodiments of the invention related to a light emitting diode, and in particular to a light emitting diode that is capable of producing light of any desired color, including white light.

### BACKGROUND OF THE INVENTION

A light-emitting diode (LED) is a semiconductor/solid state device that acts as a light source. LEDs are used as indicator lamps in many devices, and are increasingly used for lighting. When a light-emitting diode is forward biased (switched on), electrons are able to recombine with holes within the device, releasing energy in the form of photons. This effect is called electroluminescence and the color of the light (corresponding to the energy of the photon) is determined by the energy gap of the semiconductor.

An LED is usually small in area (less than 1 mm2), and integrated optical components are used to shape its radiation pattern and assist in reflection. LEDs present many advantages over incandescent light sources including lower energy consumption, longer lifetime, improved robustness, smaller size, faster switching, and greater durability and reliability.

LEDs powerful enough for room lighting are relatively expensive and require more precise current and heat management than compact fluorescent lamp sources of comparable output.

Light-emitting diodes are used in applications as diverse as replacements for aviation lighting, automotive lighting (particularly indicators) and in traffic signals. The compact size of LEDs has allowed new text and video displays and sensors to be developed, while their high switching rates are useful in advanced communications technology. Infrared LEDs are also used in the remote control units of many commercial products including televisions, DVD players, and other domestic appliances.

### SUMMARY OF THE INVENTION

Embodiments of the invention provide light emitting diode comprising a plurality of active regions, wherein each of the plurality of active regions being configured to produce a distinct emission falling within a primary wavelength range, the light emitting diode further configured to mix of each of the distinct emission falling within the primary wavelength range to produce an output emission in a wavelength range of a desired color. In a further embodiment the LED has at least three active regions. In yet a further embodiment, the plurality of active regions is coupled to a configuring unit, wherein the configuring unit comprises at least one of a control unit and a switching unit.

In a further embodiment, the control unit is configured to control the intensity of the distinct emission from the plurality of active regions, and the switching unit configured to control the active state of the plurality of active regions, where the active state is at least on of ON or OFF.

In a further embodiment, the plurality of active region is at least one of a semiconducting material or a quantum dot or a mixture of a semiconducting material and quantum dots. In yet a further embodiment, the distinct emission falling in the primary wavelength region arises from a first active region and is in a red wavelength range, the distinct emission falling in the primary wavelength region arises from a second active region and is in a blue wavelength range, and the distinct emission falling in the primary wavelength region arises from a third active region and is in a green wavelength range. In yet a further embodiment by controlling the intensity of the primary wavelength emission being emitted from the plurality of active regions by the control unit and controlling the active state of the plurality of active regions by the switching unit, light of a desired color point is obtained. In a further embodiment a lamp comprising at least one LED as described above is configured to generate an emission of a desired color.

In a further embodiment, a method for generating light of a desired color, by generating distinct emissions in a primary wavelength range from a plurality of active regions, wherein each of the distinct emission arises form each of the plurality of active regions; and mixing each of the distinct emission produced by each of the plurality of active regions thereby generating an output emission in a wavelength of a desired color point. In a further embodiment the intensity of each of the distinct emission in the primary wavelength range are controlled using the control unit; and an active state of each of the plurality of active regions is controlled by a switching unit, thereby obtaining an output emission of a desired color point. The distinct emission falling in the primary wavelength region arising from a first active region is in a red wavelength range, the distinct emission falling in the primary wavelength region arising from a second active region is in a blue wavelength range; and the distinct emission falling in the primary wavelength region arising from a third active region is in a green wavelength range. In one embodiment, white light is produced when each of the plurality of active regions is in an ON state and the intensity of the emission from each of the plurality of active regions is set to a maximum.

In a further embodiment, a light emitting diode comprising a plurality of semiconductor devices configured to emit light in at least a first wavelength range, a second wavelength range, and a third wavelength range; a plurality of FTL logic drive circuits that independently control each of the plurality of semiconductor devices, wherein the plurality FTL logic circuits comprise a common cathode; and a mixing chamber that mixes light from the plurality of semiconductor devices to produce light of a desired color.

Additional features and advantages are realized through the embodiments of the invention. Other embodiments and aspects of the invention are described in detail herein and are considered to be part of the claimed invention. For a better understanding of embodiments the invention with advantages and features, reference is made to the description and to the drawings.

### BRIEF DESCRIPTION OF THE DRAWINGS

These and further aspects of embodiments the invention will become apparent with reference made to the accompanying drawings. The drawings illustrate embodiments of the invention, and together with the description, serve to further explain the embodiments disclosed. In the drawings

FIG. 1 is an exemplary embodiment of a light emitting diode 100 as known in the art;

FIG. 2A is an exemplary embodiment of a plot 200 of wavelength (in nanometers) versus Intensity

FIG. 2B is an exemplary embodiment of a plot 250 of a color rendering index known in the art;

FIG. 3 is an exemplary embodiment of a light emitting diode 300 in accordance with the present invention;

FIG. 4 illustrates an exemplary embodiment of a LED Lamp containing the LED 300;

FIG. 5 is an exemplary application of the LED 300 used as a traffic signal.

### DETAILED DESCRIPTION OF THE INVENTION

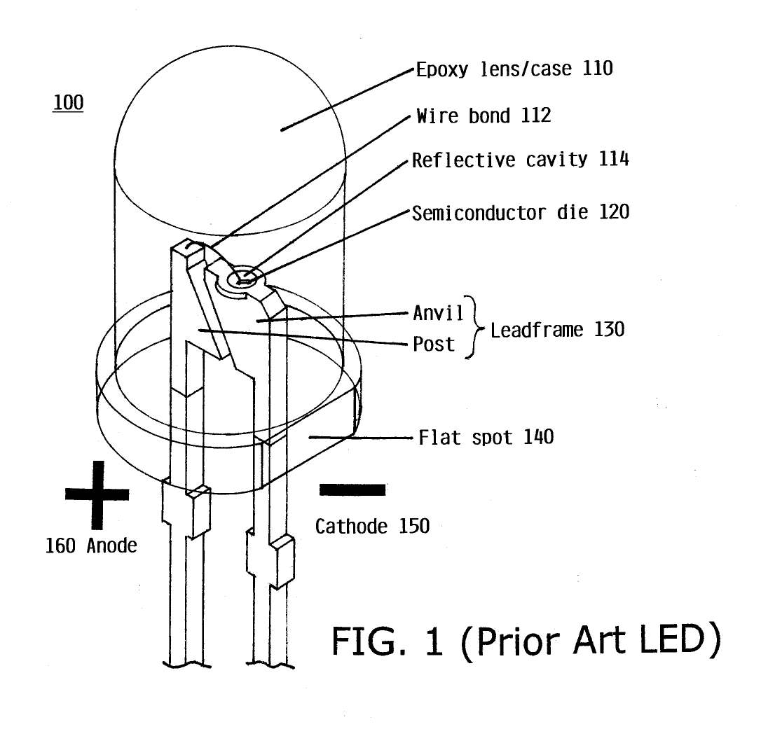

FIG. 1 is an exemplary light emitting diode (LED) 100 as known in the art. LED 100 has epoxy cover or a case or a package 110, typically made of a solid material covering the inner elements of the LED 100. For example plastic or any transparent material that allows propagation of light within minimal absorption. The package is placed around elements that make the LED bulb, much like the glass of an incandescent bulb, to hold the rest of it place and protect and bulb and the user. The color of the plastic does not dictate the color of the light.

The LED Chip—Also known as the “LED die” or “semiconductor die” 120. This chip is a light emitting semi-conductor and the central piece of an LED light. The chip sits in the center of the bulb, surrounded by the other three pieces, and is the portion of the bulb that actually lights up. The die is placed within a reflective cavity 114.

Wire Bond 112—typically made of gold or a noble metal with high conductivity. The wire 112 of an LED is used to connect the metal pin at the top of the chip to the lead frame 130. The wire allows the electricity from the frame to carry into the chip which makes it light up.

Lead Frame 130—The lead frame 130 holds the chip in place, and connected to it by the wire. The frame extends through the bottom of the bulb forming the anode 160 and the cathode 150, and provides the actual connection to the electrical source.

The LED 100 consists of a chip of semiconducting material doped with impurities to create a p-n junction 120. As in other diodes, current flows easily from the p-side, or anode 160, to the n-side, or cathode 150, but not in the reverse direction. Charge-carriers—electrons and holes—flow into the junction from electrodes with different voltages. When an electron meets a hole, it falls into a lower energy level, and releases energy in the form of a photon. The wavelength of the light emitted, and thus its color, depends on the band gap energy of the materials forming the p-n junction. For example, in silicon or germanium diodes, the electrons and holes recombine by a non-radiative transition which produces no optical emission, because these are indirect band gap materials. The materials used for the LED have a direct band gap with energies corresponding to near-infrared, visible or near-ultraviolet light. Many semiconductor LEDs also use a substrate, for example, sapphire.

LED development began with infrared and red devices made with gallium arsenide. Advances in materials science have enabled making devices with ever-shorter wavelengths, emitting light in a variety of colors. LEDs are usually built on an n-type substrate, with an electrode attached to the p-type layer deposited on its surface. P-type substrates, while less common, occur as well. Many commercial LEDs, especially GaN/InGaN, also use sapphire substrate. Most materials used for LED production have very high refractive indices. This means that much light will be reflected back into the material at the material/air surface interface.

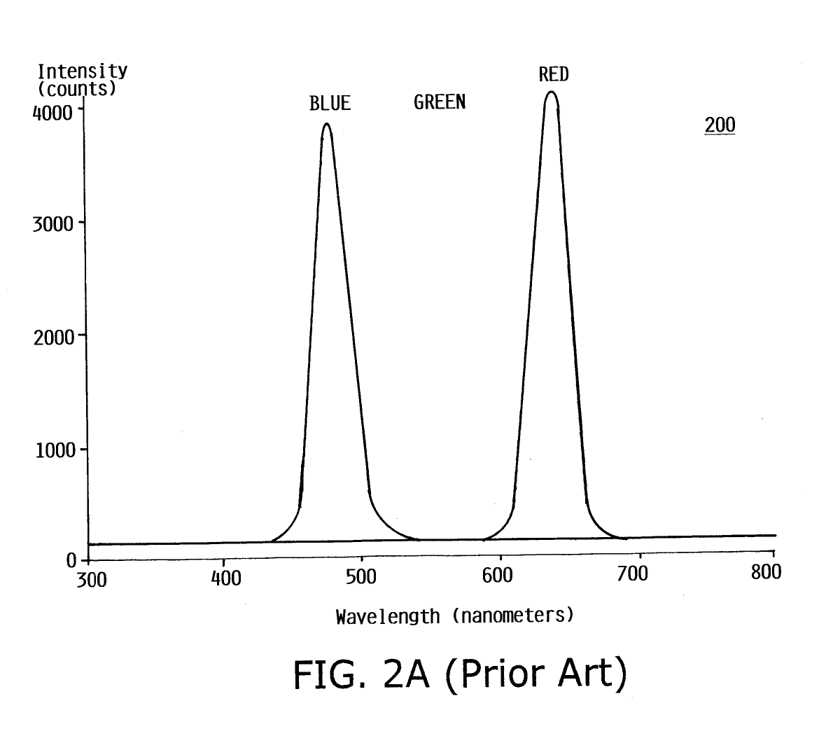

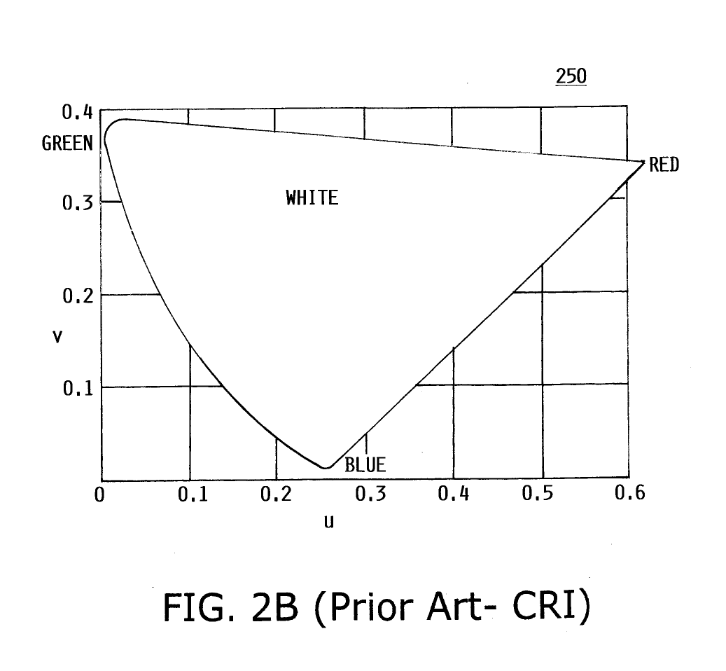

Reference is now made to FIG. 2A, illustrating a plot 200 of wavelength (in nanometers) versus intensity. The red, green and blue intensity from a typical LED is shown in FIG. 2A. FIG. 2B illustrates a plot of a color rendering index (CRI), which is a quantitative measure of the ability of a light source to reproduce the colors of various objects faithfully in comparison with an ideal or natural light source. FIG. 2B illustrates Planckian locus and co-ordinates of several illuminants. The CRI is calculated by comparing the color rendering of the test source to that of a “perfect” source which is a black body radiator for sources with correlated color temperatures under 5000 K. It should be obvious that white light can be formed by mixing differently colored lights, and the most common and simplest method is to use red, green and blue (RGB), primary colors being mixed to form white light. This mechanism of mixing primary color has higher quantum efficiency in producing white light than other known methods, for example, of using phosphor based materials to convert light of a primary color to a secondary color and then mixing the primary and secondary color to produce white light.

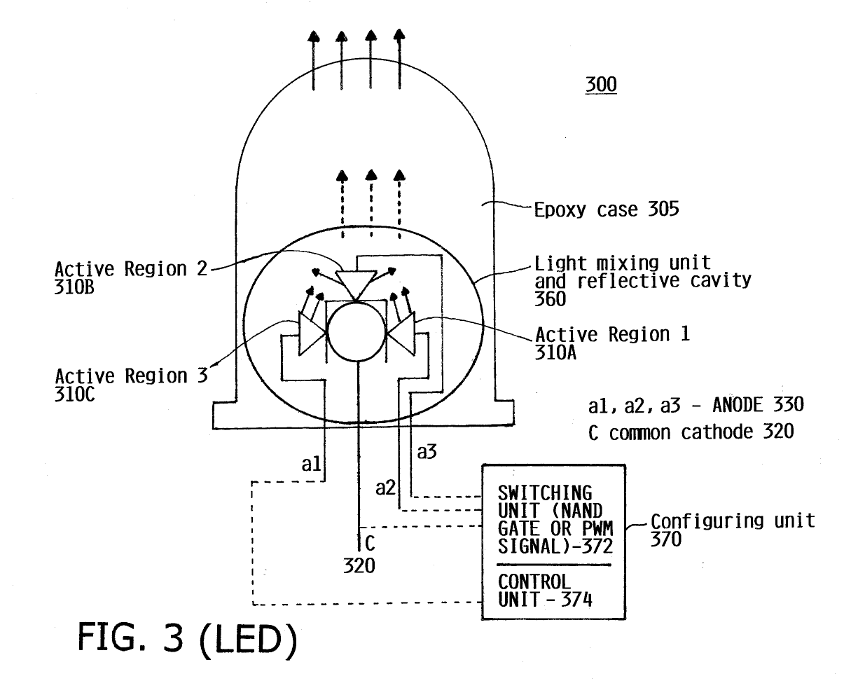

FIG. 3 illustrates an exemplary embodiment of an LED 300 in accordance with the present invention. The LED 300 contains an epoxy lens/case 305, within which the active ingredients of the LED are incorporated. The epoxy lens/case 305 protects the assembly, holds the other components in place, and allows for propagation of light with minimal absorption. The LED 300 contains three active regions (active region 1 310A; active region 2 310B; active region 3 310). These active regions are typically semiconductor dies or quantum dots or any organic material configured to emit light. Each of these active regions, i.e., Active region 1 310A, active region 2 310B and active region 3 310C are configured to emit a distinct radiation/emission falling in the primary wavelength range. For example active region 1 310A produces an emission in the red wavelength range, active region 2 310B produces an emission in the blue wavelength range and active region 3 310C produces an emission in the green wavelength. Each of these active regions 310A, 310B and 310C have a distinct anode a1 (anode corresponding to active region 1 310A), a2 (anode corresponding to active region 2 310B), and a3 (anode corresponding to active region 3 310C), and the active regions 310A, 310B and 310C coupled to a common cathode 320.

When a bias is applied to the LED, the LED becomes operational. The configuring unit 370 is configured to control the color of light being emitted from the LED 300 by switching on the appropriate active regions 310A, 310B and 310C by means of the switching unit 372, and is also further configured to control the intensity of the emission from the active region 310A, 310B and 310C of the LED by means of the control unit 374. In an exemplary embodiment, when the active region 310A is switched ON and the active region 310B is OFF and active region 310C is OFF, the LED 300 is configured to emit RED light. However, the intensity of the red light emitted from the active region can be controlled using the control unit 374. As an example in one embodiment, the control unit 374 can be a variable resistor. Other components for controlling are intensity of emissions that are obvious to one skilled in the art also fall within the scope of this invention. Switching unit 372 is configured to switch ON or OFF the appropriate active region 310A, 310B and 310C depending on the color of the output light required. Once light is emitted from the active regions, a light mixing unit (reflective cavity) 360 is configured to mix the emissions from the different active regions to produce an out emission of a desired color. The switching units in one embodiment can comprise DLT NAND gates; however other means of switching known to one skilled in the art fall within the scope of the present invention.

For example, if the intensity of the emission being produces from all the three active regions 310A, 310B and 310C is set at a maximum and all three active regions 310A, 310B and 310C are configured to be in the ON state, then active region 1 310A produced an emission in the red wavelength range, active region 2 310B produced an emission in the blue wavelength range and active region 3 310C produced an emission in the green wavelength range, and three distinct emission shown in FIG. 2A will be produced. These are typically referred to as primary wavelength emissions (red, blue and green) and mixing these emission produced from the active regions 310A, 310B and 310C at maximum intensity will finally result in the production of white light from the LED 300.

In a further embodiment, if active region 310A is set to an active state ON and the active regions 310B and 310C are set the state OFF, and the intensity is set to a maximum, the LED 300 produces pure red light. However, by varying the intensity of the red light being emitted from the active region 310A by the control unit 374, a desired color within the red spectrum can be produced. Similarly by setting active region 310B in the ON state and the other active regions 310A and 310C in the OFF state, only blue light is produced, and by setting active region 310C in the ON state and the other active regions 310A and 310B in the OFF state, green light is produced. Therefore, by selecting the appropriate active region to be in the ON state (using the switching unit) and controlling the intensity (using the control unit), light of any desired color as illustrated in the color rendering index chart 250 of FIG. 2B may be obtained from LED 300. FIG. 2B is a quantitative measure of the ability of a light source (LED 300) to reproduce the colors in comparison with an ideal or natural light source.

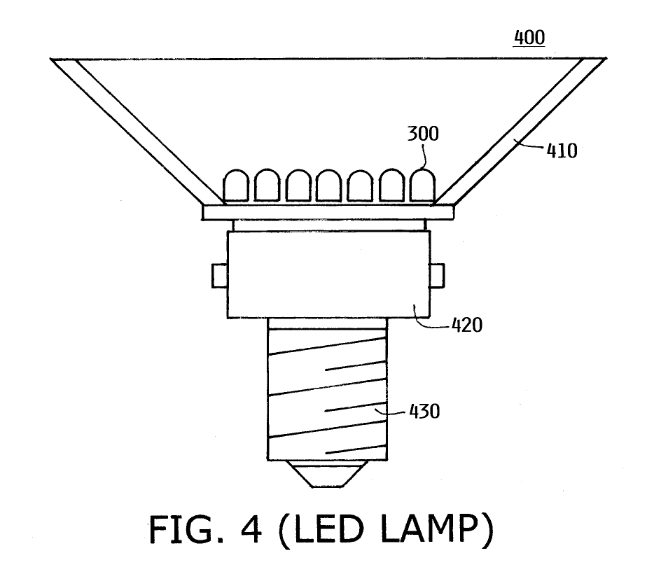

FIG. 4 illustrates an exemplary embodiment of a lamp 400 constructed by assembling at least one LED 300 as shown in FIG. 3. Typically, several LEDs 300 are combined to form a lamp 400. The lamp comprises a reflector 410, which is a highly polished surface to reflect light generated from the lamp, a power supply unit 420 for supplying power to the LEDs 300, and a base 430.

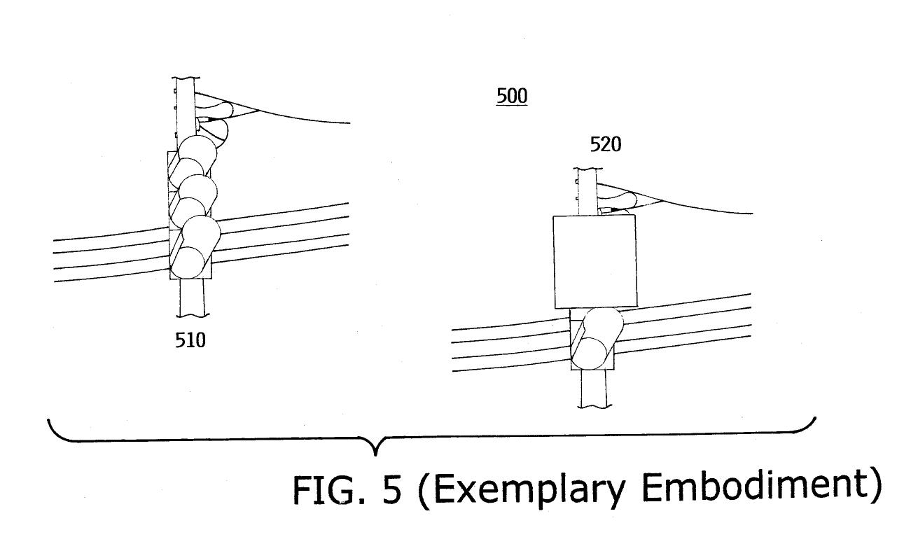

FIG. 5 provides an exemplary embodiment of the use of the invention 510, illustrating the currently use at traffic signals, where three separate colored lights are used. With the use of the current LED 300 as disclosed in FIG. 3 a single light can be used instead of a number of different color light, as the intensity and active region can provide light of a desired color. For example for red light, active region 1 310A is set at maximum intensity. Similarly for orange light mixing of red light from active region 1 310A and green light from active region 3 310C with appropriate intensities can be mixed.

In a further embodiment, at least one or more LEDs 300 forming an array can be advantageously used to be assembled into a backlight unit for lighting up display devices, such as liquid crystal display device, provides illumination to the display panel where an adjustable color temperature and high contrast can be advantageously provided to improve readability and viewing on the display depending on the application in use.

The accompanying figures and this description depicted and described embodiments of the present invention, and features and components thereof. Those skilled in the art will appreciate that any nomenclature and/or illustrations used in this description was merely for convenience, and thus the invention should not be limited to use solely in any specific application identified and/or implied by such nomenclature. Therefore, it is desired that the embodiments described herein be considered in all respects as illustrative, not restrictive, and that reference be made to the appended claims for determining the scope of the invention.

Although the invention has been described with reference to the embodiments described above, it will be evident that other embodiments may be alternatively used to achieve the same object. The scope of the invention is not limited to the embodiments described above, but can also be applied to software programs and computer program products in general. It should be noted that the above-mentioned embodiments illustrate rather than limit the invention and that those skilled in the art will be able to design alternative embodiments without departing from the scope of the appended claims. In the claims, any reference signs should not limit the scope of the claim. The invention can be implemented by means of hardware comprising several distinct elements

When a single element or article is described herein, it will be apparent that more than one element/article (whether or not they cooperate) may be used in place of a single element/article. Similarly, where more than one element or article is described herein (whether or not they cooperate), it will be apparent that a single element/article may be used in place of the more than one element or article. The functionality and/or the features of an element may be alternatively represented by one or more other elements which are not explicitly described as having such functionality/features. Thus, other embodiments need not include the element itself.

Although embodiments of the invention have been described with reference to the embodiments described above, it will be evident that other embodiments may be alternatively used to achieve the same object. The scope is not limited to the embodiments described above, but can also be applied to software and computer program products in general. It should be noted that the above-mentioned embodiments illustrate rather than limit the invention and that those skilled in the art will be able to design alternative embodiments without departing from the scope of the appended claims. In the claims, any reference signs should not limit the scope of the claim. Embodiments of the invention can be implemented by hardware comprising several distinct elements

What is claimed is:

1. A light emitting diode (LED), wherein the LED comprises a plurality of active regions, each of the plurality of active regions of the LED configured to produce a distinct emission falling within a primary wavelength range, the LED further configured to control the intensity of the distinct emission from each of the plurality of active regions, thereby producing an output emission in a wavelength range of any desired color.

2. The LED as claimed in claim 1, wherein the light emitting diode comprises at least three active regions.

3. The LED as claimed in claim 1, wherein the distinct emission produced from the at least one of the plurality of active regions does not overlap with a distinct emission produced from the at least one other of the plurality of active regions.

4. The LED as claimed in claim 1, wherein the LED includes a configuring unit and the configuring unit comprises at least one of a control unit and a switching unit.

5. The LED as claimed in claim 4, wherein the intensity of emission from each of the plurality of active regions is controlled using the control unit.

6. The LED as claimed in claim 4, wherein the switching unit is configured to control a state of the plurality of active regions.

7. The LED as claimed in claim 5, wherein the state is at least one of an ON state or OFF state.

8. The LED as claimed in claim 7, wherein the active region is configured to produce the distinct emission falling in the primary wavelength range when the state of the active region is ON.

9. The LED as claimed in claim 1, wherein at least one of the primary wavelength ranges includes emission in the red wavelength region.

10. The LED as claimed in claim 1, wherein at least one of the primary wavelength ranges includes emission in the blue wavelength region.

11. The LED as claimed in claim 1, wherein at least one of the primary wavelength ranges includes emission in the green wavelength region.

12. The LED as claimed in claim 1, wherein the plurality of active region is at least one of a semiconducting material or a quantum dot or a mixture of a semiconducting material and quantum dots or an organic material or an inorganic material or a combination thereof and being capable of producing emission.

13. The LED as claimed in claim 1, wherein the LED is configured to produce white light when the intensity of the distinct emission falling in the primary wavelength is set to a maximum and all the three active regions are in the ON state.

14. A lamp, comprising at least one light emitting diode (LED), wherein the LED comprises:
a plurality of active regions, each of the plurality of active regions of the LED configured to produce a distinct emission falling within a primary wavelength range, the LED further configured to control the intensity of the distinct emission from each of the plurality of active regions, thereby producing an output emission in a wavelength of any desired color.

15. The lamp of claim 14, wherein the lamp is configured to generate multiple emissions of any desired color.

16. The lamp of claim 14, wherein the lamp is configured for use as a backlight unit.

17. A method for generating light of a desired color, the method comprising
generating distinct emissions in a primary wavelength range from a plurality of active regions, wherein each of the distinct emission arises form each of the plurality of active regions and is different from each other; and
mixing each of the distinct emission produced by each of the plurality of active regions, thereby producing an output emission in a wavelength of any desired color point.

18. The method as claimed in claim 17, further comprising
controlling the intensity of each of the distinct emission in the primary wavelength range; and
controlling an active state of each of the plurality of active regions.

19. The method as claimed in claim 17, wherein the distinct emission falling in the primary wavelength region arising from a first active region is in a red wavelength range, and the distinct emission falling in the primary wavelength region arising from a second active region is in a blue wavelength range; and the distinct emission falling in the primary wavelength region arising from a third active region is in a green wavelength range.

20. The method as claimed in claim 17, wherein white light is produced when each of the plurality of active regions is in an ON state and the intensity of the emission from each of the plurality of active regions is set to a maximum.

21. A light emitting diode, comprising:
a plurality of semiconductor devices configured to emit light in at least a first wavelength range, a second wavelength range, and a third wavelength range;
a plurality of FTL logic drive circuits that independently control each of the plurality of semiconductor devices, wherein the plurality FTL logic circuits comprise a common cathode; and
a mixing chamber that mixes light from the plurality of semiconductor devices to produce light of a desired color.
